(19) United States
(12) Patent Application Publication
(10) Pub. No.: US 2026/0107639 A1
(43) Pub. Date: Apr. 16, 2026

(54) DISPLAY DEVICE, METHOD OF MANUFACTURING THE DISPLAY DEVICE, AND ELECTRONIC APPARATUS INCLUDING THE DISPLAY DEVICE

(71) Applicant: Samsung Display Co., Ltd., Yongin-si (KR)

(72) Inventors: Youngmin KIM, Yongin-si (KR); Haeil PARK, Yongin-si (KR)

(21) Appl. No.: 19/275,104

(22) Filed: Jul. 21, 2025

(30) Foreign Application Priority Data
Oct. 16, 2024 (KR) 10-2024-0140875

(51) Int. Cl. H10K 59/122; H10K 59/12; H10K 59/80

(52) U.S. Cl. CPC H10K 59/122; H10K 59/1201; H10K 59/80518

(57) ABSTRACT

A display device, an electronic apparatus including the display device, and a method of manufacturing the display device are disclosed. The display device may include a substrate having pixel areas including a first pixel area, a second pixel area, and a third pixel area, a pixel circuit on the substrate, reflective electrodes respectively provided in the pixel areas, a first inorganic layer over the substrate entirely, a first pixel electrode provided in the first pixel area and contacting the pixel circuit, a second inorganic layer in the second pixel area and the third pixel area, a second pixel electrode provided in the second pixel area and contacting the pixel circuit, a third inorganic layer in the third pixel area, a third pixel electrode provided in the third pixel area and contacting the pixel circuit, and a pixel defining layer.

### CROSS-REFERENCE TO RELATED APPLICATION

The present application claims priority to and the benefit of Korean Patent Application No. 10-2024-0140875, filed on Oct. 16, 2024, in the Korean Intellectual Property Office, the entire disclosure of which is incorporated herein by reference.

### BACKGROUND

### 1. Field

One or more embodiments of the present disclosure relate to a display device, a method of manufacturing the display device, and an electronic apparatus including the display device.

### 2. Description of the Related Art

Display devices, such as organic light-emitting diode (OLED) display devices, include transistors, connection electrodes, and wirings in the sub-pixels so as to control the luminance and/or the like of the sub-pixels.

### SUMMARY

One or more aspects of embodiments of the present disclosure are directed toward a display device having ultra-high resolution, a method of manufacturing the display device, and an electronic apparatus including the display device.

Additional aspects of embodiments will be set forth in part in the description which follows and, in part, will be apparent from the description or may be learned by practice of the presented embodiments of the disclosure.

According to one or more embodiments, a display device includes a substrate having pixel areas that include a first pixel area, a second pixel area, and a third pixel area, a pixel circuit on the substrate, reflective electrodes provided on the substrate and respectively arranged or provided in the pixel areas, a first inorganic layer that covers the reflective electrodes and is arranged or provided over the entire substrate (or over the substrate entirely), a first pixel electrode that is arranged or provided in the first pixel area on the first inorganic layer and contacts the pixel circuit, a second inorganic layer that covers the first inorganic layer and is arranged or provided in the second pixel area and the third pixel area, a second pixel electrode that is arranged or provided in the second pixel area on the second inorganic layer and contacts the pixel circuit, a third inorganic layer that covers the second inorganic layer and is arranged or provided in the third pixel area, a third pixel electrode that is arranged or provided in the third pixel area on the third inorganic layer and contacts the pixel circuit, and a pixel defining layer that includes pixel openings, that respectively correspond to pixel electrodes (e.g., the first pixel electrode, the second pixel electrode, and the third pixel electrode), and covers edges of the pixel electrodes (e.g., the first pixel electrode, the second pixel electrode, and the third pixel electrode), wherein contacts of each of the pixel electrodes (e.g., each of the first pixel electrode, the second pixel electrode, and the third pixel electrode) and the pixel circuit are in an area that overlaps the pixel defining layer.

Each of the contacts may be outside an emission area defined by each of the pixel openings.

Each of the reflective electrodes may have an isolated shape that corresponds to each of the pixel areas.

Each of the reflective electrodes may have an area equal to or larger than an area of each of the pixel openings.

Each of the reflective electrodes may include a material having a reflectivity higher than a reflectivity of each of the pixel electrodes (e.g., each of the first pixel electrode, the second pixel electrode, and the third pixel electrode).

Each of the reflective electrodes may include a stack of a transmissive conductive (e.g., electrically conductive) layer and a reflective metal layer.

Each of the first inorganic layer, the second inorganic layer, and the third inorganic layer may include a transmissive inorganic material.

The reflective electrodes may include a first reflective electrode arranged or provided in the first pixel area and having an isolated shape, a second reflective electrode arranged or provided in the second pixel area and having an isolated shape, and a third reflective electrode arranged or provided in the third pixel area and having an isolated shape, wherein a distance between the first reflective electrode and the first pixel electrode, a distance between the second reflective electrode and the second pixel electrode, and a distance between the third reflective electrode and the third pixel electrode may be different from each other.

Each of the first pixel electrode, the second pixel electrode, and the third pixel electrode may include a transmissive conductive (e.g., electrically conductive) oxide.

Each of the first pixel electrode, the second pixel electrode, and the third pixel electrode may have an area larger than an area of each of the first reflective electrode, the second reflective electrode, and the third reflective electrode that corresponds thereto.

Each of the first pixel electrode, the second pixel electrode, and the third pixel electrode may include a protrusion that protrudes outside an emission area defined by each of the pixel openings on a plane parallel (e.g., substantially parallel) to the substrate, and the protrusion may overlap the pixel defining layer.

According to one or more embodiments, a method of manufacturing a display device includes preparing a substrate having pixel areas that include a first pixel area, a second pixel area, and a third pixel area, forming or providing a pixel circuit on the substrate, forming or providing reflective electrodes in the pixel areas, respectively, forming or providing a first inorganic layer that covers the reflective electrodes over the entire substrate (or over the substrate entirely), forming or providing a first pixel electrode that is arranged or provided in the first pixel area on the first inorganic layer and contacts the pixel circuit, forming or providing a second inorganic layer that covers the first inorganic layer and is arranged or provided in the second pixel area and the third pixel area, forming or providing a second pixel electrode that is arranged or provided in the second pixel area on the second inorganic layer and contacts the pixel circuit, forming or providing a third inorganic layer that covers the second inorganic layer and is arranged or provided in the third pixel area, forming or providing a third pixel electrode that is arranged or provided in the third pixel area on the third inorganic layer and contacts the pixel circuit, and forming or providing a pixel defining layer that includes pixel openings, that respectively correspond to pixel electrodes (e.g., the first pixel electrode, the second pixel electrode, and the third pixel electrode), and covers edges of the pixel electrodes (e.g., the first pixel electrode, the second pixel electrode, and the third pixel electrode), wherein contacts of each of the pixel electrodes (e.g., each of the first pixel electrode, the second pixel electrode, and the third pixel electrode) and the pixel circuit are in an area that overlaps the pixel defining layer.

Each of the reflective electrodes may have an isolated shape that corresponds to each of the pixel areas.

Each of the reflective electrodes may include a material having a reflectivity higher than a reflectivity of each of the pixel electrodes (e.g., each of the first pixel electrode, the second pixel electrode, and the third pixel electrode).

Each of the reflective electrodes may include a stack of a transmissive conductive (e.g., electrically conductive) layer and a reflective metal layer.

Each of the first inorganic layer, the second inorganic layer, and the third inorganic layer may include a transmissive inorganic material.

Each of the first pixel electrode, the second pixel electrode, and the third pixel electrode may include a transmissive conductive (e.g., electrically conductive) oxide.

The method may further include forming or providing an intermediate layer that includes an emission layer in the pixel openings, and forming or providing an opposite electrode over the entire substrate (or over the substrate entirely) to cover the intermediate layer.

The intermediate layer may be formed or provided over the entire substrate (or over the substrate entirely), and the method may further include forming or providing an encapsulation layer on the opposite electrode, and forming or providing a color filter layer on the encapsulation layer.

The pixel defining layer may be formed or provided to directly cover contacts of each of the pixel electrodes (e.g., each of the first pixel electrode, the second pixel electrode, and the third pixel electrode) and the pixel circuit.

According to one or more embodiments, an electronic apparatus includes a display device, wherein the display device includes a substrate having pixel areas that include a first pixel area, a second pixel area, and a third pixel area, a pixel circuit on the substrate, reflective electrodes provided on the substrate and respectively arranged or provided in the pixel areas, a first inorganic layer that covers the reflective electrodes and is arranged or provided over the entire substrate (or over the substrate entirely), a first pixel electrode that is arranged or provided in the first pixel area on the first inorganic layer and contacts the pixel circuit, a second inorganic layer that covers the first inorganic layer and is arranged or provided in the second pixel area and the third pixel area, a second pixel electrode that is arranged or provided in the second pixel area on the second inorganic layer and contacts the pixel circuit, a third inorganic layer that covers the second inorganic layer and is arranged or provided in the third pixel area, a third pixel electrode that is arranged or provided in the third pixel area on the third inorganic layer and contacts the pixel circuit, and a pixel defining layer that includes pixel openings, that respectively correspond to pixel electrodes (e.g., the first pixel electrode, the second pixel electrode, and the third pixel electrode), and covers edges of the pixel electrodes (e.g., the first pixel electrode, the second pixel electrode, and the third pixel electrode), wherein contacts of each of the pixel electrodes (e.g., each of the first pixel electrode, the second pixel electrode, and the third pixel electrode) and the pixel circuit are arranged or provided in an area that overlaps the pixel defining layer.

Each of the contacts may be outside an emission area defined by each of the pixel openings.

Each of the first pixel electrode, the second pixel electrode, and the third pixel electrode may include a protrusion that protrudes outside an emission area defined by each of the pixel openings on a plane parallel (e.g., substantially parallel) to the substrate, and the protrusion may overlap the pixel defining layer.

### BRIEF DESCRIPTION OF THE DRAWINGS

The above and/or other aspects and features of certain embodiments of the present disclosure will become more apparent and more readily appreciated from the following description of one or more embodiments, taken in conjunction with the accompanying drawings in which:

FIG. 1 is a plan view schematically illustrating a display device according to one or more embodiments;

FIGS. 2A and 2B are plan views schematically illustrating a portion of a display device according to one or more embodiments;

FIG. 3 is a cross-sectional view schematically illustrating the display device of FIG. 2A taken along the line B-B′ of FIG. 2A;

FIGS. 4A-10B are cross-sectional views (upper side; FIGS. 4A-10A) and plan views (lower side; FIGS. 4B-10B) sequentially illustrating a process or method of manufacturing the display device of FIG. 3; and

FIG. 11A is a photograph of the display device according to a comparative example. FIG. 11B is an explanatory diagram of the display device according to the comparative example. FIG. 11C is an explanatory diagram of the display device according to one or more embodiments, which has a better aperture ratio than the comparative example.

### DETAILED DESCRIPTION

As the present description allows for one or more suitable changes to the disclosed subject matter and embodiments, certain embodiments will be illustrated in the accompanying drawings and described in more detail in the written description. The aspects, effects, and/or embodiments of the present disclosure and methods of achieving them will be clarified with reference to one or more embodiments and the accompanying drawings described below in more detail. However, the disclosure is not limited to the disclosed embodiments and may be embodied in one or more suitable forms.

In one or more embodiments, the terms, “first,” “second,” and/or the like, are not used in a restrictive sense and are used to distinguish one element from another. For instance, the first element may be termed the second element, and vice versa, without departing from the spirit and scope of the present disclosure.

The terms, such as “below,” “lower,” “above,” “upper,” and/or the like, are used herein for ease of description to describe one element's relation to another element(s) as illustrated in the drawings. These terms are relative concepts and are described based on the directions indicated in the drawings.

The singular forms as used herein are intended to include the plural forms as well unless the context clearly indicates otherwise.

The term “and/or” shall include the combination of a plurality of listed items or any of the plurality of listed items.

It will be further understood that the terms, “has,” “include,” “having,” and/or “including,” used herein specify the presence of stated features or elements, but do not preclude the presence or addition of one or more other features or elements.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In one or more embodiments, it will be understood that, if (e.g., when) a portion, such as a layer, a film, a plate, a unit, a region, or an element, is referred to as being “on” another portion, this may include not only a case where the portion is directly on the other portion, but also a case where intervening portions may be present therebetween. In contrast, if (e.g., when) a portion is referred to as being “directly on” another portion, there may be no intervening portions present therebetween.

In one or more embodiments, it will be understood that the terms, “connection” or “coupling,” do not necessarily refer to as being “direct and/or fixed connection or coupling” of two members, unless the context clearly indicates otherwise, and this does not preclude the disposition of other members between the two members.

Also, the sizes of elements in the drawings may be exaggerated or reduced to effectively or suitably illustrate the technical contents of the present disclosure. For example, because the sizes and/or the thicknesses of elements in the drawings are arbitrarily illustrated for convenience of explanation, embodiments of the present disclosure are not limited thereto.

The x-axis, the y-axis, and the z-axis are not limited to three axes of the rectangular coordinate system and may be interpreted in a broader sense. For example, the x-axis, the y-axis, and the z-axis may be perpendicular (e.g., substantially perpendicular) to one another or may represent different directions that are not perpendicular to one another.

Unless otherwise defined, all terms, including technical terms and scientific terms, used herein have substantially the same meaning as how they are generally understood by those of ordinary skill in the art to which the present disclosure pertains. Any term that is defined in a general dictionary shall be construed to have substantially the same meaning in the context of the relevant art and, unless otherwise defined explicitly, shall not be interpreted to have an idealistic or excessively formalistic meaning.

Hereinafter, the subject matter of the present disclosure will be described in more detail with reference to the accompanying drawings. If (e.g., when) describing one or more embodiments with reference to the accompanying drawings, substantially the same or corresponding elements are denoted by the same reference numerals, and redundant descriptions thereof may not be provided.

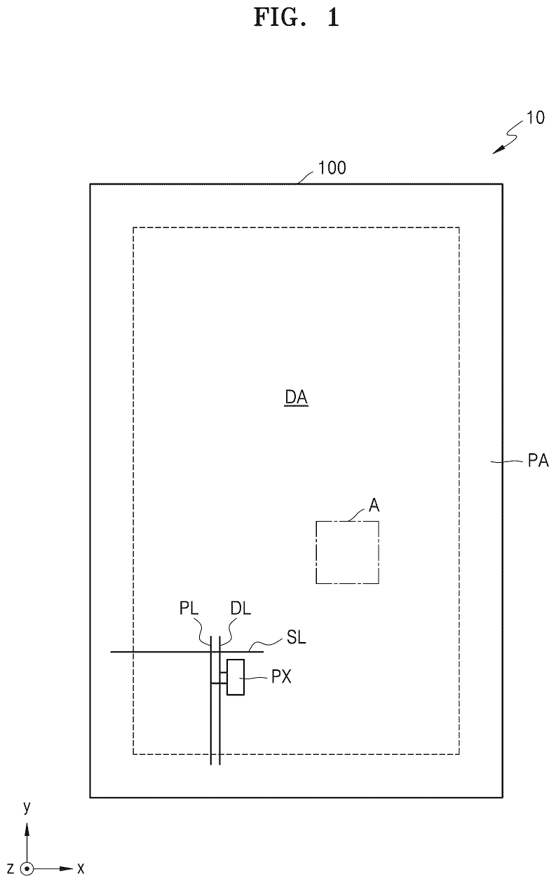

FIG. 1 is a plan view schematically illustrating a display device 10 according to one or more embodiments.

Referring to FIG. 1, the display device 10 may include a display panel. One or more embodiments of the present disclosure may be applied to any suitable type or kind of display device as long as the display device includes a display panel. The display device 10 according to one or more embodiments of the present disclosure may be one or more suitable products, such as a display panel included in a head-mounted display (HMD), a smartphone, a tablet, a laptop, a television, and/or a billboard.

The display device 10 may include a display area DA and a peripheral area PA outside the display area DA. The display area DA may be a portion that displays an image. A plurality of pixels PX may be in the display area DA. If (e.g., when) viewed from a direction (a z-axis direction) about perpendicular (e.g., substantially perpendicular) to a plane parallel (e.g., substantially parallel) to the display device 10, the display area DA may have one or more suitable shapes, for example, a circular shape (a substantially circular shape), an elliptical shape (a substantially elliptical shape), a polygonal shape (e.g., a substantially polygonal shape), or a specific figure shape.

Each of the pixels PX may include a display element. Each of the pixels PX may emit light. The pixel PX may be connected to a pixel circuit that includes a thin-film transistor (TFT), a storage capacitor, and/or the like. The pixel circuit may be connected to a scan line SL arranged or provided to transmit a scan signal, a data line DL that crosses (e.g., intersects) the scan line SL and is arranged or provided to transmit a data signal, and a driving voltage line PL arranged or provided to supply a driving voltage. The scan line SL may extend in an x-axis direction, and the data line DL and the driving voltage line PL may extend in a y-axis direction.

The pixel PX may be arranged or provided to emit light of a luminance that corresponds to an electrical signal from the pixel circuit electrically connected thereto. The display area DA may allow a certain image to be displayed through light emitted from the pixel PX. For reference, as described in one or more embodiments, the pixel PX may be defined as an area arranged or provided to emit red light, green light, or blue light.

The peripheral area PA may be outside the display area DA. The peripheral area PA may be an area in which no pixels PX are arranged or provided and an area that does not display an image. A power supply line and/or the like arranged or provided to drive the pixel PX may be in the peripheral area PA. In one or more embodiments, a terminal part and/or the like to which a driver integrated circuit (IC) and/or a printed circuit board including a driver circuit is connected may be connected in the peripheral area PA.

Because the display device 10 includes a first substrate 100, the first substrate 100 may have the display area DA and the peripheral area PA as described in one or more embodiments. For convenience, the following description is given on the assumption that the first substrate 100 has the display area DA and the peripheral area PA. One or more suitable components included in the display device 10 may be on the first substrate 100. The first substrate 100 may include glass, metal, and/or a polymer resin.

Hereinafter, an organic light-emitting diode display device is described as an example of the display device 10 according to one or more embodiments. However, the display device 10 of the disclosure is not limited thereto. In one or more embodiments, the display device 10 according to the present disclosure may be an inorganic light-emitting diode display or an inorganic electroluminescence (EL) display, or may be a display device, such as a quantum dot light-emitting display. For example, an emission layer of a display element included in the display device 10 may include an organic material and/or an inorganic material. In one or more embodiments, the display device 10 may include an emission layer and a quantum dot layer on a path of light emitted from the emission layer.

Hereinafter, a white organic light-emitting diode (WOLED) display device that utilizes a WOLED-color filter (CF) method of employing a color filter in a WOLED may be described as an example of the organic light-emitting diode display device according to one or more embodiments. The WOLED may be implemented by forming or providing a plurality of organic emission materials, which emit a red color, a green color, and a blue color, within an organic emission layer, or by forming or providing pairs of two organic emission materials having a complementary color relationship.

In one or more embodiments, the HMD may include a mixed reality (MR) headset, a virtual reality (VR) headset, and/or the like. The HMD may include a display panel to provide a screen to a user, a sensor to measure a user's motion, biometric value, and/or the like to enable the user to interact with the real world, a convex lens arranged or provided between the display panel and a user's eyes and to adjust focus, and a protective cushion to block or reduce a user's peripheral vision. The display panel may correspond to the display device 10. A display device for an HMD may be desirable or required to ensure or provide a wide field of view (FOV) so as to enhance user immersion. However, as the display device ensures or provides a wide FOV, pixels per degree (PPD) may decrease. As the PPD decreases, a screen door effect may occur, causing increased visual fatigue and reduced realism for users. To minimize or reduce a screen door effect for a particular HMD, it is desirable or required for pixels per inch (PPI) be about 6,000. Because the WOELD display device as described in one or more embodiments is manufactured by utilizing an open mask instead of a fine metal mask, it may be designed to maximize or increase PPI, which is beneficial to provide high resolution.

In one or more embodiments, in the WOLED-CF method, white light has to be filtered out through a CF. Accordingly, the light transmittance may be relatively low, compared to an independent deposition method. If (e.g., when) applying the WOLED-CF method, the light transmittance may be about 25%, compared to the independent deposition method. To solve the problem of low light transmittance, a resonance structure may be applied to an OLED. The light transmittance of the OLED to which the resonance structure is applied may be improved or enhanced by about 30% to about 50%, compared to a non-resonance structure.

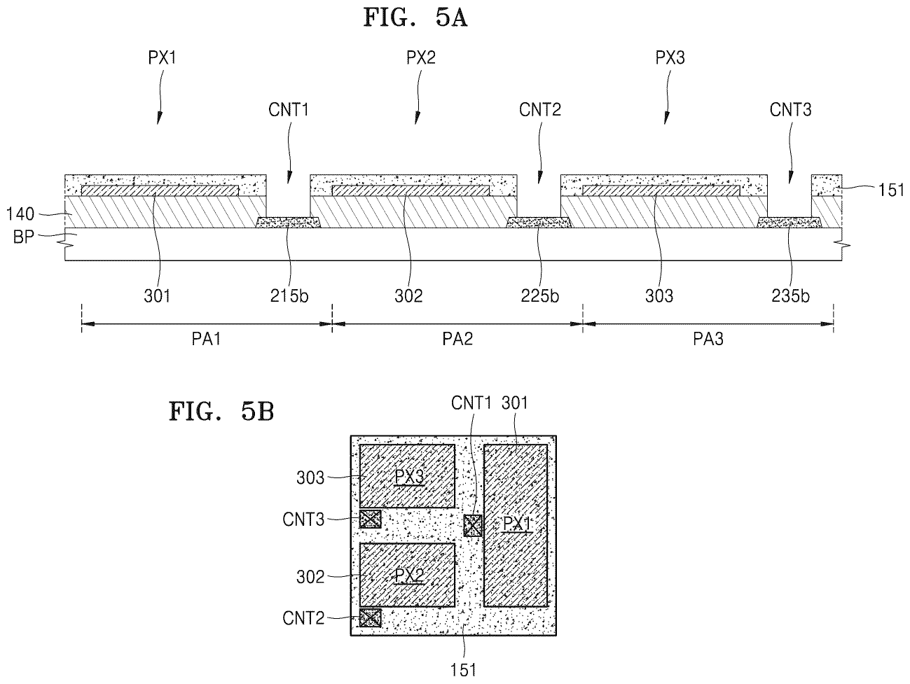

If (e.g., when) the resonance structure is applied to the OLED, a differential pixel electrode may be formed or provided for each sub-pixel. The differential pixel electrode may be formed or provided so that a contact portion to which a pixel circuit is connected overlaps an emission portion of the OLED, which causes a reduction in aperture ratio. This is described herein in more detail with reference to FIG. 5.

According to one or more embodiments, a structure and a manufacturing method for achieving or providing both (e.g., simultaneously) maximum light extraction efficiency and aperture ratio in the WOLED display device are provided herein in more detail.

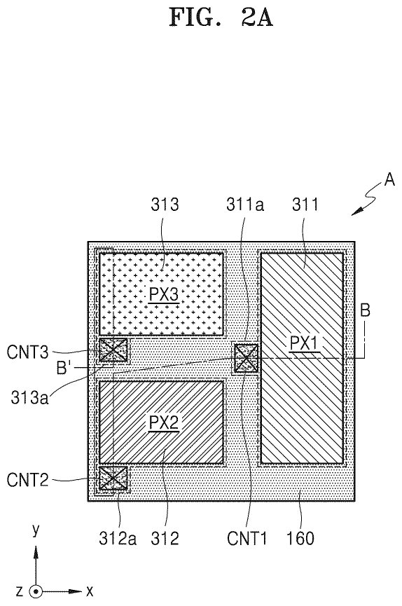

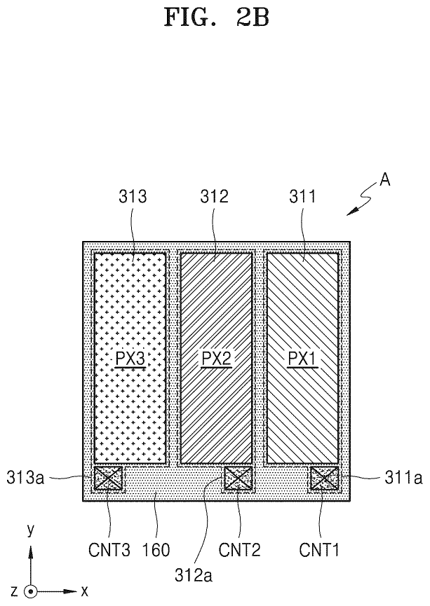

FIGS. 2A and 2B are plan views schematically illustrating a portion of the display device according to one or more embodiments. FIG. 2A may be an enlarged plan view of region A of FIG. 1.

Referring to FIG. 2A, the display device 10 may include a plurality of pixels PX1, PX2, and PX3. The pixels PX1, PX2, and PX3 may include a first pixel PX1, a second pixel PX2, and a third pixel PX3 to emit substantially the same color. The first pixel PX1 may be a pixel that implements blue light by a blue color filter that is formed or provided later, the second pixel PX2 may be a pixel that implements green light by a green color filter that is formed or provided later, and the third pixel PX3 may be a pixel that implements red light by a red color filter that is formed or provided later.

Each of the first pixel PX1, the second pixel PX2, and the third pixel PX3 may have a polygonal shape (e.g., a substantially polygonal shape) if (e.g., when) viewed from a direction (the z-axis direction) perpendicular (e.g., substantially perpendicular) to the first substrate 100. In FIGS. 2A and 2B, each of the first pixel PX1, the second pixel PX2, and the third pixel PX3 is illustrated as having a rectangular shape (e.g., a substantially rectangular shape) if (e.g., when) viewed from a direction (the z-axis direction) perpendicular (e.g., substantially perpendicular) to the first substrate 100. However, embodiments of the present disclosure are not limited thereto. For example, each of the first pixel PX1, the second pixel PX2, and the third pixel PX3 may have a rectangular shape (e.g., a substantially rectangular shape) with round corners, a circular shape (a substantially circular shape), or an elliptical shape (a substantially elliptical shape) if (e.g., when) viewed from a direction (the z-axis direction) perpendicular (e.g., substantially perpendicular) to the first substrate 100.

The sizes, e.g., the areas of the first pixel PX1, the second pixel PX2, and the third pixel PX3 may be different from each other. For example, the area of the first pixel PX1 may be larger than the area of the second pixel PX2 and the area of the third pixel PX3. However, embodiments of the present disclosure are not limited thereto. For example, the areas of the first pixel PX1, the second pixel PX2, and the third pixel PX3 may be substantially equal to each other.

The arrangement of the first pixel PX1, the second pixel PX2, and the third pixel PX3 may be suitably modified. For example, the second pixel PX2 and the third pixel PX3 may be parallel (e.g., substantially parallel) to each other in the x-axis direction, and the first pixel PX1 may be in the y-axis direction perpendicular (e.g., substantially perpendicular) to the x-axis direction. For example, referring to FIG. 2B, the first pixel PX1, the second pixel PX2, and the third pixel PX3 may be in a stripe type or kind. In one or more embodiments, the first pixel PX1, the second pixel PX2, and the third pixel PX3 may be arranged or provided side-by-side in the x-axis direction, or may be arranged or provided side-by-side in the y-axis direction. However, embodiments of the present disclosure are not limited thereto. The first pixel PX1, the second pixel PX2, and the third pixel PX3 may be in a PENTILE® type or kind or a mosaic type or kind. PENTILE® is a duly registered trademark of Samsung Display Co., Ltd.

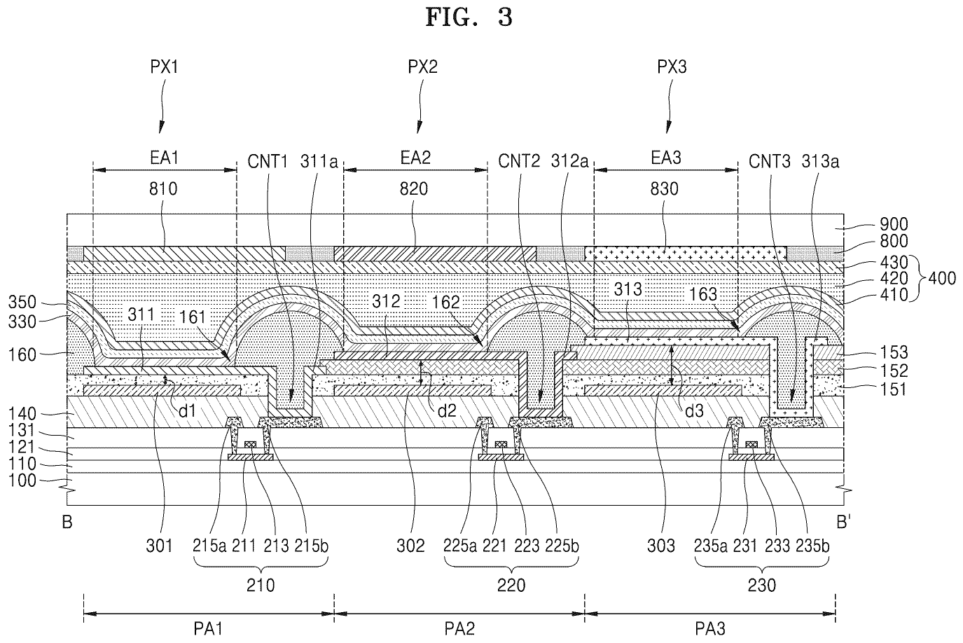

The first pixel PX1 may include a first pixel electrode 311, the second pixel PX2 may include a second pixel electrode 312, and the third pixel PX3 may include a third pixel electrode 313. If (e.g., when) viewed from a direction (the z-axis direction) perpendicular (e.g., substantially perpendicular) to the first substrate 100, the first pixel electrode 311 may include a first protrusion 311a and contact the pixel circuit through the first protrusion 311a, the second pixel electrode 312 may include a second protrusion 312a and contact the pixel circuit through the second protrusion 312a, and the third pixel electrode 313 may include a third protrusion 313a and contact the pixel circuit through the third protrusion 313a. A pixel defining layer 160 may define emission areas (e.g., a first emission area EA1, a second emission area EA2, and a third emission area EA3 of FIG. 3) through pixel openings (e.g., a first pixel opening 161, a second pixel opening 162, and a third pixel opening 163 of FIG. 3). The pixel defining layer 160 may cover the edges of the first pixel electrode 311, the second pixel electrode 312, and the third pixel electrode 313. In one or more embodiments, the pixel defining layer 160 may cover the first protrusion 311a, the second protrusion 312a, and the third protrusion 313a. In one or more embodiments, the portions where the first pixel PX1, the second pixel PX2, and the third pixel PX3 contact the pixel circuit may be in areas that overlap the pixel defining layer 160.

According to one or more embodiments, the pixel electrodes respectively may include the protrusions, and the protrusions that contact the pixel circuit may be in areas that overlap the pixel defining layer. Accordingly, there may be an effect of maximizing or increasing the aperture ratio.

FIG. 3 is a cross-sectional view schematically illustrating the display device of FIG. 2A taken along the line B-B′ of FIG. 2A.

The display device according to one or more embodiments of the present disclosure may include a first substrate 100, a pixel circuit portion, an OLED portion, an encapsulation layer 400, color filter layers 800, and a second substrate 900.

The first substrate 100 may include glass, metal, and/or a polymer resin. The first substrate 100 may include, for example, a polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. In one or more embodiments, one or more suitable modifications may be feasible. For example, the first substrate 100 may have a multilayer structure that includes two layers and a barrier layer therebetween, wherein the two layers may include a polymer resin and the barrier layer may include an inorganic material (e.g., silicon oxide, silicon nitride, silicon oxynitride, and/or the like).

A pixel circuit may be on the first substrate 100. Pixels PX1, PX2, and PX3 may include separate pixel circuits. Each of the pixel circuits may include at least two TFTs and at least one storage capacitor. Although FIG. 3 illustrates only one TFT 210, 220, and 230 respectively included in the pixels, embodiments of the present disclosure are not limited thereto. Hereinafter, a pixel area refers to an area that corresponds to each pixel. The terms “pixel” and “pixel area” may be often used interchangeably. If (e.g., when) viewed from the x-axis direction perpendicular (e.g., substantially perpendicular) to the first substrate 100, the area of the pixel area may be larger than the area of the emission area.

A first TFT 210 may be in a first pixel area PA1 that corresponds to a first pixel PX1, a second TFT 220 may be in a second pixel area PA2 that corresponds to a second pixel PX2, and a third TFT 230 may be in a third pixel area PA3 that corresponds to a third pixel PX3. As illustrated in FIG. 3, the first TFT 210 may be electrically connected to a first pixel electrode 311, the second TFT 220 may be electrically connected to a second pixel electrode 312, and the third TFT 230 may be electrically connected to a third pixel electrode 313. The first pixel electrode 311, the second pixel electrode 312, and the third pixel electrode 313 may be on inorganic layers (e.g., 151, 152, and 153) as described in one or more embodiments, which may be on the first substrate 100.

The first TFT 210 may include a first semiconductor layer 211, a first gate electrode 213, a first source electrode 215a, and a first drain electrode 215b. The first semiconductor layer 211 may include amorphous (e.g., non-crystalline) silicon, polycrystalline silicon, an organic semiconductor material, and/or an oxide semiconductor material. The first gate electrode 213 may include one or more suitable conductive (e.g., electrically conductive) materials and have one or more suitable layered structures. For example, the first gate electrode 213 may include a molybdenum (Mo) layer and an aluminum (Al) layer. In one or more embodiments, the first gate electrode 213 may have a layered structure of Mo/Al/Mo. In one or more embodiments, the first gate electrode 213 may include a titanium nitride (e.g., TiNₓ, wherein 0<X≤2; e.g., TiN) layer, an Al layer, and/or a titanium (Ti) layer. Each of the first source electrode 215a and the first drain electrode 215b may also include one or more suitable conductive (e.g., electrically conductive) materials and have one or more suitable layered structures. For example, each of the first source electrode 215a and the first drain electrode 215b may include a Ti layer, an Al layer, and/or a copper (Cu) layer. In one or more embodiments, each of the first source electrode 215a and the first drain electrode 215b may have a layered structure of Ti/Al/Ti.

Although FIG. 3 illustrates that the first TFT 210 includes both (e.g., simultaneously) the first source electrode 215a and the first drain electrode 215b, embodiments of the present disclosure are not limited thereto. For example, a source region of the first semiconductor layer 211 of the first TFT 210 may be integral with a drain region of a semiconductor layer of another TFT. In one or more embodiments, the first TFT 210 may not have the first source electrode 215a. In one or more embodiments, the first source electrode 215a and/or the first drain electrode 215b may be a portion of a wiring.

In order to ensure or provide electrical insulation between the first semiconductor layer 211 and the first gate electrode 213, a gate insulating layer 121 including an inorganic material, such as silicon oxide, silicon nitride, and/or silicon oxynitride, may be arranged or provided between the first semiconductor layer 211 and the first gate electrode 213. In one or more embodiments, an interlayer insulating layer 131 including an inorganic material, such as silicon oxide, silicon nitride, and/or silicon oxynitride, may be arranged or provided above the first gate electrode 213. The first source electrode 215a and the first drain electrode 215b may be arranged or provided on the interlayer insulating layer 131. The insulating (e.g., electrically insulating) layer including the inorganic material as described in one or more embodiments, such as the gate insulating layer 121 and the interlayer insulating layer 131, may be formed or provided by chemical vapor deposition (CVD) and/or atomic layer deposition (ALD). Substantially the same applies to one or more embodiments and modifications as described herein.

A buffer layer 110 including an inorganic material, such as silicon oxide, silicon nitride, and/or silicon oxynitride, may be between the first substrate 100 and the first TFT 210 having the structure as described in one or more embodiments. The buffer layer 110 may increase or enhance the smoothness of the top surface of the first substrate 100 or may prevent or minimize infiltration of impurities (or reduce a degree or occurrence of infiltration of impurities) from the first substrate 100 and/or the like into the first semiconductor layer 211 of the first TFT 210.

The second TFT 220 in the second pixel area PA2 of the second pixel PX2 may include a second semiconductor layer 221, a second gate electrode 223, a second source electrode 225a, and a second drain electrode 225b. The third TFT 230 in the third pixel area PA3 of the third pixel PX3 may include a third semiconductor layer 231, a third gate electrode 233, a third source electrode 235a, and a third drain electrode 235b. Because the structure of the second TFT 220 and the structure of the third TFT 230 are substantially identical to or similar to the structure of the first TFT 210 in the first pixel PX1, a description thereof may not be provided.

A planarization layer 140 may be on the first TFT 210. For example, if (e.g., when) the OLED is arranged or provided above the first TFT 210 as illustrated in FIG. 3, the planarization layer 140 that covers the first TFT 210 may have a substantially flat top surface, and thus, the OLED may be arranged or provided on the substantially flat surface. The planarization layer 140 may include, for example, an organic material, such as an acryl-based resin or compound, benzocyclobutene (BCB), and/or hexamethyldisiloxane (HMDSO). In FIG. 3, the planarization layer 140 is illustrated as a single layer, but the planarization layer 140 may be suitably modified. For example, the planarization layer 140 may be a multilayer.

An OLED having a first reflective electrode 301, a first pixel electrode 311, an opposite electrode 350, and an intermediate layer 330 therebetween and including an emission layer may be arranged or provided in the first pixel PX1.

The first reflective electrode 301 may be on the planarization layer 140 that corresponds to the first pixel area PA1. The first reflective electrode 301 may have an isolated shape that corresponds to the first pixel area PA1. In one or more embodiments, the first reflective electrode 301 may not be electrically connected to the pixel circuit or the pixel electrode through a contact. Accordingly, the display device 10 may implement a resonance structure between the first reflective electrode 301 and the opposite electrode 350 while ensuring or providing the maximum aperture ratio. The first reflective electrode 301 may be at a position that corresponds to the first pixel opening 161 as described in one or more embodiments, and the area of the first reflective electrode 301 may be equal to or larger than the area of the first pixel opening 161. Because the first pixel opening 161 defines the first emission area EA1, the area of the first reflective electrode 301 may be equal to or larger than the area of the first emission area EA1. Therefore, the first reflective electrode 301 may implement a resonance structure having an optimal area. The first reflective electrode 301 may include a material having a reflectivity higher than a reflectivity of the first pixel electrode 311. The first reflective electrode 301 may include a reflective metal layer having relatively high reflectivity. The first reflective electrode 301 may have a stacked structure of a transmissive conductive (e.g., electrically conductive) layer and a reflective metal layer. The first reflective electrode 301 may include a transmissive conductive (e.g., electrically conductive) layer including a transmissive conductive (e.g., electrically conductive) oxide, such as indium tin oxide (ITO), In₂O₃, and/or indium zinc oxide (IZO), and/or a reflective metal layer including metal, such as Al and/or silver (Ag). For example, the first reflective electrode 301 may have a three-layer structure of ITO/Ag/ITO. The first reflective electrode 301 may be implemented having a thickness of about 500 angstroms to about 1,600 angstroms. If (e.g., when) the thickness of the first reflective electrode 301 is less than about 500 angstroms, the reflection efficiency may be low and the resonance may be difficult to achieve. If (e.g., when) the thickness of the first reflective electrode 301 is greater than about 1,600 angstroms, the resonance efficiency may be poor due to excessive reflection.

The first pixel electrode 311 may be insulated (e.g., electrically insulated) from the first reflective electrode 301 and may be in the first pixel area PA1 so as to overlap the first reflective electrode 301. As illustrated in FIG. 3, the first pixel electrode 311 may be electrically connected to the first TFT 210 while contacting one selected from the first source electrode 215a and the first drain electrode 215b through a first contact hole CNT1 that is in a first inorganic layer 151 and the planarization layer 140. A first contact between the first pixel electrode 311 and the first TFT 201 may be in an area that overlaps the pixel defining layer 160. In one or more embodiments, the first contact between the first pixel electrode 311 and the first TFT 210 may be outside the first emission area EA1 defined by the pixel defining layer 160. If (e.g., when) viewed from a direction (the z-axis direction) perpendicular (e.g., substantially perpendicular) to the first substrate 100, the first pixel electrode 311 may include a first protrusion 311a that contacts the first TFT 210. The first protrusion 311a may be in an area that overlaps the pixel defining layer 160 and may be outside the first emission area EA1. Accordingly, the display device 10 according to one or more embodiments of the present disclosure may be arranged or provided so that the first reflective electrode 301, which is a reflective mirror for the resonance structure, is separated from the first pixel electrode 311 and the first pixel electrode 311 contacts the pixel circuit. Because the contact is outside the first emission area EA1, the resonance structure may be implemented while solving the problem that the aperture ratio is reduced due to the contact. The first pixel electrode 311 may include a transmissive conductive (e.g., electrically conductive) layer including a transmissive conductive (e.g., electrically conductive) oxide, such as ITO, In₂O₃, and/or IZO. The first pixel electrode 311 may be implemented having a thickness of about 100 angstroms to about 1,000 angstroms. If (e.g., when) the thickness of the first pixel electrode 311 is less than about 100 angstroms, the electrical resistance may increase and the electrical conduction may not be achieved efficiently or suitably. If (e.g., when) the thickness of the first pixel electrode 311 is greater than about 1,000 angstroms, the transparency may decrease and the light emission efficiency may deteriorate.

The first inorganic layer 151 may be between the first reflective electrode 301 and the first pixel electrode 311. The first inorganic layer 151 may be over the entire substrate (or over the substrate entirely) to cover, in addition to the first reflective electrode 301, the second reflective electrode 302 of the second pixel area PA2, and the third reflective electrode 303 of the third pixel area PA3. The first inorganic layer 151 may include a material having a low absorption coefficient and high transmittance. For example, the first inorganic layer 151 may include an inorganic material, such as silicon nitride, silicon oxide, and/or silicon oxynitride. In one or more embodiments, the first inorganic layer 151 may include silicon oxide having a low absorption coefficient. The thickness of the first inorganic layer 151 may be in a range of about 100 angstroms to about 2,000 angstroms. If (e.g., when) the thickness of the first inorganic layer 151 is less than about 100 angstroms, the resonance effect may not occur properly or suitably. If (e.g., when) the thickness of the first inorganic layer 151 is greater than about 2,000 angstroms, the resonance frequency may change. Accordingly, light may be strengthened at wavelengths other than an originally intended wavelength and optical loss may increase.

An OLED having a second reflective electrode 302, a second pixel electrode 312, an opposite electrode 350, and an intermediate layer 330 therebetween and including an emission layer may be in the second pixel PX2.

The second reflective electrode 302 may be on the planarization layer 140 that corresponds to the second pixel area PA2 and may have an isolated shape that corresponds to the second pixel area PA2. In one or more embodiments, the description of the first reflective electrode 301 may also be applied to the second reflective electrode 302.

The second pixel electrode 312 may be insulated (e.g., electrically insulated) from the second reflective electrode 302 and may be in the second pixel area PA2 so as to overlap the second reflective electrode 302. The description of the first pixel electrode 311 may also be applied to the second pixel electrode 312. However, the second pixel electrode 312 may differ from the first pixel electrode 311 in that the second pixel electrode 312 may be on the second inorganic layer 152 that is on the first inorganic layer 151, as illustrated in FIG. 3. Accordingly, the second pixel electrode 312 may be electrically connected to the second TFT 220 while contacting one selected from the second source electrode 225a and the second drain electrode 225b through a second contact hole CNT2 that is in the planarization layer 140, the first inorganic layer 151, and the second inorganic layer 152. Similar to the first pixel electrode 311, a second contact between the second pixel electrode 312 and the second TFT 220 may be in an area that overlaps the pixel defining layer 160.

In addition to the first inorganic layer 151, a second inorganic layer 152 may be between the second reflective electrode 302 and the second pixel electrode 312. The second inorganic layer 152 may be on the second reflective electrode 302 of the second pixel area PA2 and the third reflective electrode 303 of the third pixel area PA3, excluding the first pixel area PA1. In one or more embodiments, the description of the first inorganic layer 151 may also be applied to the second inorganic layer 152.

An OLED having a third reflective electrode 303, a third pixel electrode 313, an opposite electrode 350, and an intermediate layer 330 therebetween and including an emission layer may be in the third pixel PX3.

The third reflective electrode 303 may be on the planarization layer 140 that corresponds to the third pixel area PA3 and may have an isolated shape that corresponds to the third pixel area PA3. In one or more embodiments, the description of the first reflective electrode 301 and the second reflective electrode 302 may also be applied to the third reflective electrode 303.

The third pixel electrode 313 may be insulated (e.g., electrically insulated) from the third reflective electrode 303 and may be in the third pixel area PA3 so as to overlap the third reflective electrode 303. The description of the first pixel electrode 311 and the second pixel electrode 312 may also be applied to the third pixel electrode 313. However, the third pixel electrode 313 may differ from the first pixel electrode 311 and the second pixel electrode 312 in that the third pixel electrode 313 may be on the third inorganic layer 153 that is on the second inorganic layer 152, as illustrated in FIG. 3. Accordingly, the third pixel electrode 313 may be electrically connected to the third TFT 230 through a third contact hole CNT3 that is in the planarization layer 140, the first inorganic layer 151, the second inorganic layer 152, and the third inorganic layer 153. Similar to the first pixel electrode 311 and the second pixel electrode 312, a third contact between the third pixel electrode 313 and the third TFT 230 may be in an area that overlaps the pixel defining layer 160.

In addition to the first inorganic layer 151 and the second inorganic layer 152, a third inorganic layer 153 may be further arranged or provided between the third reflective electrode 303 and the third pixel electrode 313. The third inorganic layer 153 may be on the third reflective electrode 303 of the third pixel area PA3, excluding the first pixel area PA1 and the second pixel area PA2. In one or more embodiments, the description of the first inorganic layer 151 and the second inorganic layer 152 may also be applied to the third inorganic layer 153.

According to one or more embodiments of the present disclosure, a distance d1 between the first reflective electrode 301 and the first pixel electrode 311, a distance d2 between the second reflective electrode 302 and the second pixel electrode 312, and a distance d3 between the third reflective electrode 303 and the third pixel electrode 313 may be different from each other. For example, d3 may be greater than d2, and d2 may be greater than d1. In one or more embodiments, the distance d1 between the first reflective electrode 301 and the first pixel electrode 311 may be about 100 angstroms to about 2,000 angstroms depending on the thickness of the first inorganic layer 151. The distance d2 between the second reflective electrode 302 and the second pixel electrode 312 may be about 200 angstroms to about 4,000 angstroms depending on the thickness of the first inorganic layer 151 and the second inorganic layer 152. The distance d3 between the third reflective electrode 303 and the third pixel electrode 313 may be about 300 angstroms to about 6,000 angstroms depending on the thickness of the first inorganic layer 151, the second inorganic layer 152, and the third inorganic layer 153. Accordingly, because the distances between the reflective electrodes (e.g., the first reflective electrode, the second reflective electrode, and the third reflective electrode) and the pixel electrodes (e.g., the first pixel electrode, the second pixel electrode, and the third pixel electrode) are different from each other, there may be an effect of being able to control the light spectrum for each pixel by resonating light obtained from the intermediate layer through different resonance lengths.

The pixel defining layer 160 may be on the substrate. The pixel defining layer 160 may have pixel openings 161, 162, and 163 that respectively define the emission areas EA1, EA2, and EA3. In one or more embodiments, the pixel defining layer 160 may have the first pixel opening 161 that covers the edges of the first pixel electrode 311, the second pixel electrode 312, and the third pixel electrode 313 and exposes the central portion of the first pixel electrode 311 to define the first emission area EA1, the second pixel opening 162 that exposes the central portion of the second pixel electrode 312 to define the second emission area EA2, and the third pixel opening 163 that exposes the central portion of the third pixel electrode 313 to define the third emission area EA3. As illustrated in FIG. 3, the pixel defining layer 160 may prevent an electric arc and/or the like from occurring (or reduce a degree to or occurrence of which an electric arc and/or the like occurs) on the edges of the first pixel electrode 311, the second pixel electrode 312, and the third pixel electrode 313 by increasing the distance between the edge of each of the first pixel electrode 311, the second pixel electrode 311, and the third pixel electrode 313 and the opposite electrode 350. The pixel defining layer 160 may include, for example, an organic material, such as polyimide and/or HMDSO.

The intermediate layer 330 including the emission layer may be arranged or provided not only on the first pixel electrode 311 of the first pixel PX1, but also on the second pixel electrode 312 of the second pixel PX2 and the third pixel electrode 313 of the third pixel PX3. The intermediate layer 330 may have an integral shape across the first pixel electrode 311, the second pixel electrode 312, and the third pixel electrode 313. The intermediate layer 330 may be patterned and arranged or provided on the first pixel electrode 311, the second pixel electrode 312, and the third pixel electrode 313 as desired or necessary. In addition to the emission layer, the intermediate layer 330 may also include a hole injection layer, a hole transport layer, and/or an electron transport layer as desired or necessary. The layers included in the intermediate layer 330 may also have an integral shape across the first pixel electrode 311, the second pixel electrode 312, and the third pixel electrode 313. In one or more embodiments, one or more layers included in the intermediate layer 330 may be patterned and arranged or provided on the first pixel electrode 311, the second pixel electrode 312, and the third pixel electrode 313 as desired or necessary. The emission layer included in the intermediate layer 330 may be arranged or provided to emit light of a wavelength in a first wavelength band. The first wavelength band may be, for example, about 450 nm to about 495 nm.

In one or more embodiments, the intermediate layer 330 may not include a single emission layer but may include a plurality of emission layers. For example, the intermediate layer 330 may have a structure in which a first emission layer and a second emission layer are stacked and a charge generation layer and/or the like is arranged or provided between the first emission layer and the second emission layer. In one or more embodiments, a hole transport layer or an electron transport layer may be respectively arranged or provided between the first emission layer and the charge generation layer and between the second emission layer and the charge generation layer.

The opposite electrode 350 may be on the intermediate layer 330. The opposite electrode 350 may also have an integral shape across the first pixel electrode 311, the second pixel electrode 311, and the third pixel electrode 313. The opposite electrode 350 may include a transmissive conductive (e.g., electrically conductive) layer including ITO, In₂O₃, and/or IZO, and may also include a semi-transmissive layer including metal, such as Al, lithium (Li), magnesium (Mg), ytterbium (Yb), and/or Ag.

For example, the opposite electrode 350 may be a semi-transmissive layer including MgAg, AgYb, Yb/MgAg, and/or Li/MgAg.

The organic light-emitting elements including the first pixel electrode 311, the second pixel electrode 312, the third pixel electrode 313, the intermediate layer 330 including the emission layer, and the opposite electrode 350 may be easily deteriorated by moisture and/or oxygen. Therefore, in order to protect the organic light-emitting elements from ambient moisture and/or oxygen, the display device may include the encapsulation layer 400 that covers the organic light-emitting elements.

The encapsulation layer 400 may include at least one inorganic encapsulation layer and at least one organic encapsulation layer. For example, the encapsulation layer 400 may include a first inorganic encapsulation layer 410, a second inorganic encapsulation layer 430, and an organic encapsulation layer 420 therebetween.

Each of the first inorganic encapsulation layer 410 and the second inorganic encapsulation layer 430 may include at least one inorganic insulating (e.g., electrically insulating) material selected from among silicon oxide (e.g., SiOₓ, wherein 0<X≤2; e.g., SiO₂), silicon nitride (e.g., Si₃N₄ or SiNₓ, wherein 0<X≤2), silicon oxynitride (e.g., Si₂N₂O or SiOₓN_{y}, wherein 0<X≤2 and 0≤Y≤2; e.g., SiON), aluminum oxide (Al₂O₃), titanium oxide (e.g., TiOₓ, wherein 0<X≤2; e.g., TiO₂), tantalum oxide (Ta₂O₅), hafnium oxide (HfO₂), and/or zinc oxide (e.g., ZnO or ZnO₂) and may be formed or provided by chemical vapor deposition (CVD) and/or the like. The organic encapsulation layer 420 may include a polymer-based material. The polymer-based material may include a silicone-based resin, an acrylic-based resin (e.g., polymethyl methacrylate, polyacrylic acid, and/or the like), an epoxy-based resin, polyimides, polyethylene, and/or the like.

The second substrate 900 may be arranged or provided above the first substrate 100 so that the opposite electrode 350 is arranged or provided therebetween. The second substrate 900 may include glass, metal, and/or a polymer resin. The second substrate 900 may include, for example, a polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. In one or more embodiments, one or more suitable modifications may be feasible. For example, the second substrate 900 may have a multilayer structure that includes two layers and a barrier layer therebetween, wherein the two layers may include a polymer resin and the barrier layer may include an inorganic material (e.g., silicon oxide, silicon nitride, silicon oxynitride, and/or the like).

The color filter layers 800 may be arranged or provided between the encapsulation layer 400 and the second substrate 900. A first color filter layer 810 may be arranged or provided above the first pixel PX1, a second color filter layer 820 may be arranged or provided above the second pixel PX2, and a third color filter layer 830 may be arranged or provided above the third pixel PX3. The first color filter layer 810 may be a layer arranged or provided to pass only light having a wavelength that ranges from about 450 nm to about 495 nm. The second color filter layer 820 may be a layer arranged or provided to pass only light having a wavelength that ranges from about 495 nm to about 570 nm. The third color filter layer 830 may be a layer arranged or provided to pass only light having a wavelength that ranges from about 625 nm to about 780 nm, but embodiments of the present disclosure are not limited thereto.

The first color filter layer 810, the second color filter layer 820, and the third color filter layer 830 may improve or enhance the quality of displayed images by increasing or enhancing the color purity of light emitted to the outside. In one or more embodiments, the first color filter layer 810, the second color filter layer 820, and the third color filter layer 830 may reduce a degree or occurrence of external light reflection by lowering a rate at which external light incident on the display device from the outside is reflected from the first reflective electrode 301, the second reflective electrode 302, and the third reflective electrode 303 and then emitted again to the outside. A black matrix may be arranged or provided among the first color filter layer 810, the second color filter layer 820, and the third color filter layer 830 as desired or necessary.

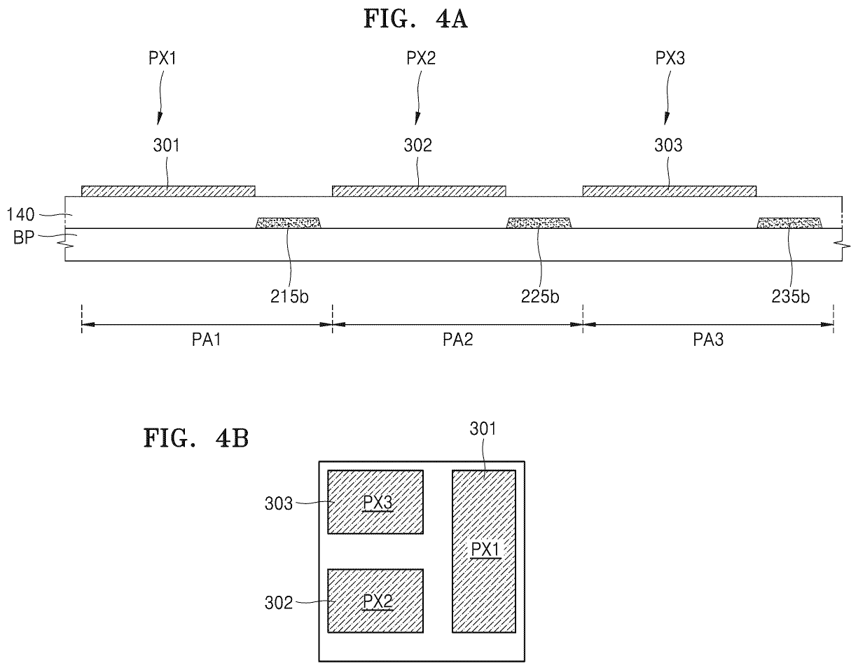

Hereinafter, a method of manufacturing the display device of FIG. 3 is described in more detail with reference to FIGS. 4A to 10B. If (e.g., when) describing FIGS. 4A to 10B, a description redundant with those provided in one or more embodiments with reference to FIG. 3 may not be provided.

FIGS. 4A to 10B are cross-sectional views (upper side; FIGS. 4A, 5A, 6A, 7A, 8A, 9A, and 10A) and plan views (lower side; FIGS. 4B, 5B, 6B, 7B, 8B, 9B, and 10B) sequentially illustrating a process of manufacturing the display device of FIG. 3. In each drawing, the cross-sectional view is denoted by (a) and the plan view is denoted by (b).

For convenience of explanation, the encapsulation layer 400, the color filter layer 800, and the second substrate 900 of FIG. 3 are not illustrated in FIGS. 4A to 10B. In one or more embodiments, for convenience of explanation, a portion of the first substrate 100 and the pixel circuit portion of FIG. 3 (e.g., the TFTs) may not be provided or may be simply illustrated as a back plane BP in FIGS. 4A to 10B.

Referring to FIGS. 4A and 4B, a pixel circuit may be formed or provided on a first substrate (100 of FIG. 3). The pixel circuit may include the TFTs as described with reference to FIG. 3. For convenience of explanation, only the first drain electrode 215b of the first TFT 210, the second drain electrode 225b of the second TFT 220, and the third drain electrode 235b of the third TFT 230 are illustrated in FIG. 4A. A planarization layer 140 may be formed or provided on the TFTs.

The reflective electrodes 301, 302, and 303 may be formed or provided on the planarization layer 140. The reflective electrodes 301, 302, and 303 may include a first reflective electrode 301, a second reflective electrode 302, and a third reflective electrode 303. The first reflective electrode 301, the second reflective electrode 302, and the third reflective electrode 303 may be respectively formed or provided at positions that correspond to a first pixel area PA1, a second pixel area PA2, and a third pixel area PA3 and may each have an isolated shape. The reflective electrodes 301, 302, and 303 may be formed or provided by forming or providing a stack of a transmissive conductive (e.g., electrically conductive) oxide layer, a reflective metal layer, and a conductive (e.g., electrically conductive) oxide layer and then patterning the stack by utilizing a mask. For example, the reflective electrodes 301, 302, and 303 may have a three-layer structure of ITO/Ag/ITO.

Referring to FIGS. 5A and 5B, a first inorganic layer 151 may be formed or provided on the planarization layer 140 to cover the reflective electrodes 301, 302, and 303. The first inorganic layer 151 may be arranged or provided over the entire substrate (or over the substrate entirely) to cover the first reflective electrode 301 of the first pixel area PA1, the second reflective electrode 302 of the second pixel area PA2, and the third reflective electrode 303 of the third pixel area PA3. The first inorganic layer 151 may include a material having a low absorption coefficient and high transmittance. For example, the first inorganic layer 151 may include silicon oxide having a low absorption coefficient. The first inorganic layer 151 may be formed or provided by CVD and/or ALD. Next, a first contact hole CNT1, a second contact hole CNT2, and a third contact hole CNT3 may be formed or provided in the planarization layer 140 and the first inorganic layer 151 through a patterning process by utilizing a mask so as to expose the first drain electrode 215b, the second drain electrode 225b, and the third drain electrode 235b, respectively.

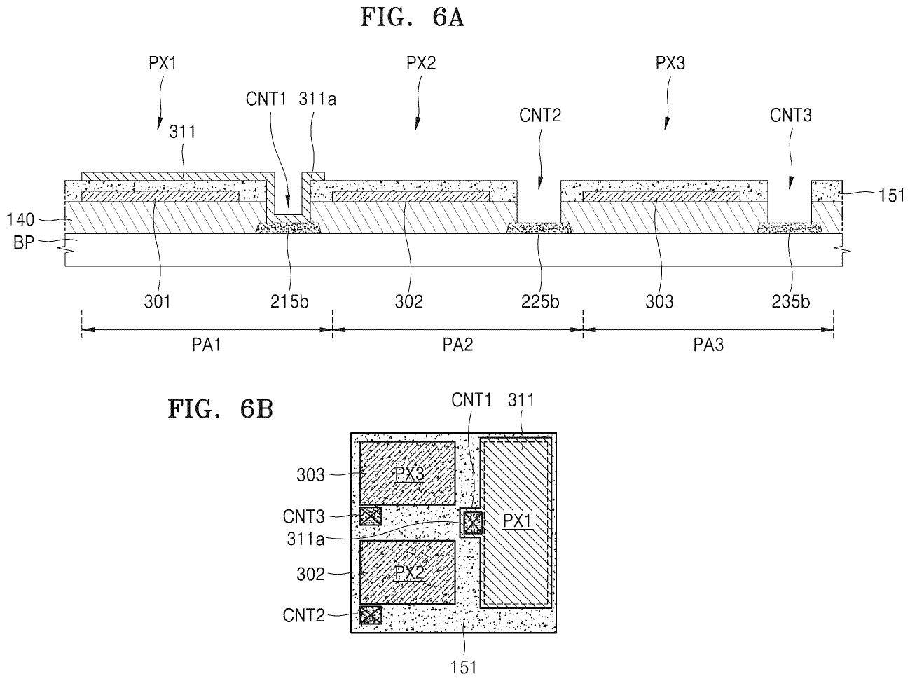

Referring to FIGS. 6A and 6B, a first pixel electrode 311 may be formed or provided on the first inorganic layer 151 of the first pixel area PA1. The first pixel electrode 311 may include a first protrusion 311a that protrudes outside the first emission area (EA1 of FIG. 3) if (e.g., when) viewed from a direction (the z-axis direction) perpendicular (e.g., substantially perpendicular) to the first substrate 100.

The first protrusion 311a may be formed or provided to protrude in a portion that corresponds to the first contact hole CNT1 and may be in contact with and electrically connected to the exposed first drain electrode 215b. The first pixel electrode 311 may be formed or provided by forming or providing a transmissive conductive (e.g., electrically conductive) oxide on the entire substrate and then patterning the transmissive conductive (e.g., electrically conductive) oxide by utilizing a mask. For example, the first pixel electrode 311 may include a transmissive conductive (e.g., electrically conductive) layer including a transmissive conductive (e.g., electrically conductive) oxide, such as ITO, In₂O₃, and/or IZO.

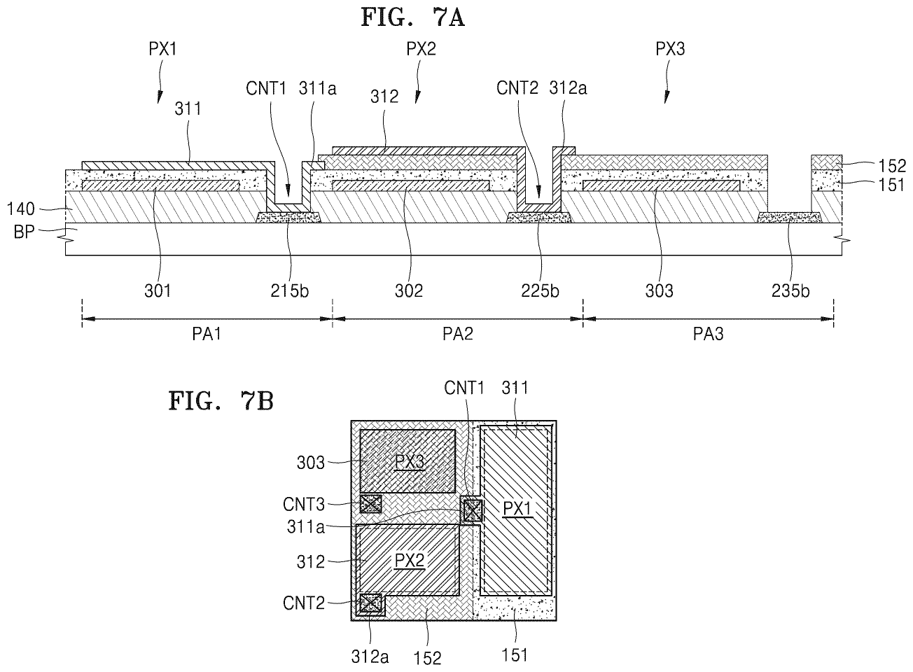

Referring to FIGS. 7A and 7B, a second inorganic layer 152 may be formed or provided on the first pixel electrode 311 and the first inorganic layer 151. The second inorganic layer 152 may be arranged or provided over the entire substrate (or over the substrate entirely) to cover the first pixel electrode 311 of the first pixel area PA1, the first inorganic layer 151 of the second pixel area PA2, and the first inorganic layer 151 of the third pixel area PA3. The second inorganic layer 152 may include a material having a low absorption coefficient and high transmittance. The second inorganic layer 152 may include substantially the same material as a material of the first inorganic layer 151. For example, the second inorganic layer 152 may include silicon oxide having a low absorption coefficient. However, embodiments of the present disclosure are not limited thereto, and the second inorganic layer 152 may include a material that is different from a material of the first inorganic layer 151. The second inorganic layer 152 may be formed or provided by CVD and/or ALD. Thereafter, an opening that exposes the first pixel electrode 311 may be formed or provided in the second inorganic layer 152 through a patterning process by utilizing a mask, and a second contact hole CNT2 and a third contact hole CNT3 may be respectively formed or provided to expose the second drain electrode 225b and the third drain electrode 235b. Due to the patterning, the second inorganic layer 152 may be formed or provided to cover the edge of the first protrusion 311a. Accordingly, undesired or unnecessary electrical contact between the first protrusion 311a and the second pixel electrode 312 may be prevented or reduced.

Thereafter, a second pixel electrode 312 may be formed or provided on the second inorganic layer 152 of the second pixel area PA2. The second pixel electrode 312 may include a second protrusion 312a that protrudes outside the second emission area (EA2 of FIG. 3) if (e.g., when) viewed from a direction (the z-axis direction) perpendicular (e.g., substantially perpendicular) to the first substrate 100. The second protrusion 312a may be formed or provided to protrude in a portion that corresponds to the second contact hole CNT2 and may be in contact with and electrically connected to the exposed second drain electrode 225b. The second pixel electrode 312 may be formed or provided by forming or providing a transmissive conductive (e.g., electrically conductive) oxide on the entire substrate and then patterning the transmissive conductive (e.g., electrically conductive) oxide by utilizing a mask. For example, the second pixel electrode 312 may include a transmissive conductive (e.g., electrically conductive) layer including a transmissive conductive (e.g., electrically conductive) oxide, such as ITO, In₂O₃, and/or IZO.

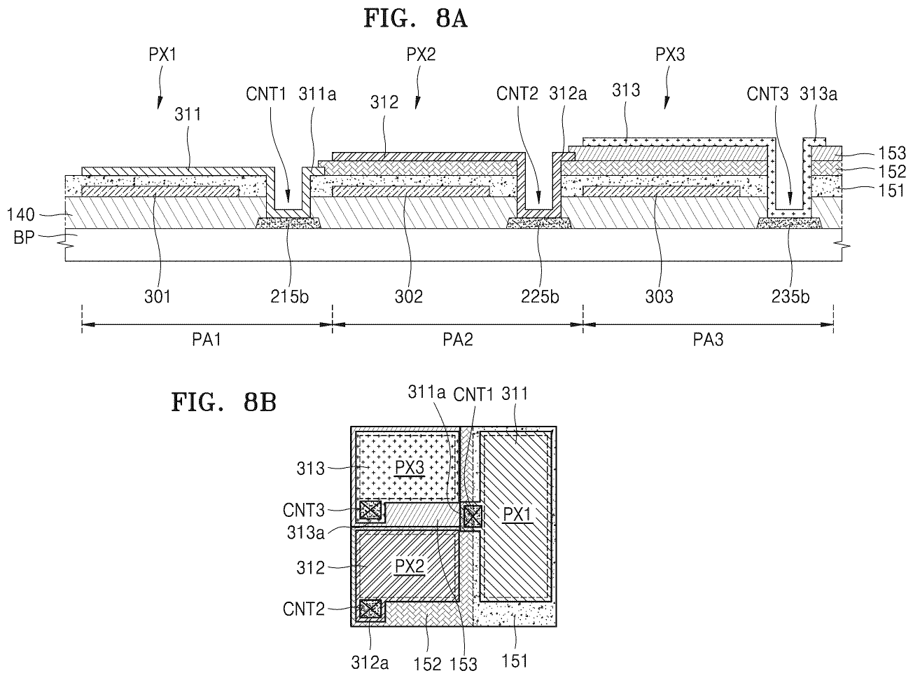

Referring to FIGS. 8A and 8B, a third inorganic layer 153 may be formed or provided on the first pixel electrode 311, the second pixel electrode 312, and the second inorganic layer 152. The third inorganic layer 153 may be arranged or provided over the entire substrate (or over the substrate entirely) to cover the first pixel electrode 311 of the first pixel area PA1, the second pixel electrode 312 of the second pixel area PA2, and the second inorganic layer 152 of the third pixel area PA3. The third inorganic layer 153 may include a material having a low absorption coefficient and high transmittance. The third inorganic layer 153 may include substantially the same material as a material of the first inorganic layer 151 and the second inorganic layer 152. For example, the third inorganic layer 153 may include silicon oxide having a low absorption coefficient. However, embodiments of the present disclosure are not limited thereto, and the third inorganic layer 153 may include a material that is different from a material of the first inorganic layer 151 and/or the second inorganic layer 152. The third inorganic layer 153 may be formed or provided by CVD and/or ALD. Thereafter, an opening that exposes the first pixel electrode 311 and the second pixel electrode 312 may be formed or provided in the third inorganic layer 153 through a patterning process by utilizing a mask, and a third contact hole CNT3 that exposes the third drain electrode 235b may be formed or provided. Due to the patterning, the third inorganic layer 153 may be formed or provided to cover the edge of the second protrusion 312a. Accordingly, undesired or unnecessary electrical contact between the second protrusion 312a and the third pixel electrode 313 may be prevented or reduced.

Thereafter, a third pixel electrode 313 may be formed or provided on the third inorganic layer 153 of the third pixel area PA3. The third pixel electrode 313 may include a third protrusion 313a that protrudes outside the third emission area (EA3 of FIG. 3) if (e.g., when) viewed from a direction (the z-axis direction) perpendicular (e.g., substantially perpendicular) to the first substrate 100. The third protrusion 313a may be formed or provided to protrude in a portion that corresponds to the third contact hole CNT3 and may be in contact with and electrically connected to the exposed third drain electrode 235b. The third pixel electrode 313 may be formed or provided by forming or providing a transmissive conductive (e.g., electrically conductive) oxide on the entire substrate and then patterning the transmissive conductive (e.g., electrically conductive) oxide by utilizing a mask. For example, the third pixel electrode 313 may include a transmissive conductive (e.g., electrically conductive) layer including a transmissive conductive (e.g., electrically conductive) oxide, such as ITO, In₂O₃, and/or IZO.

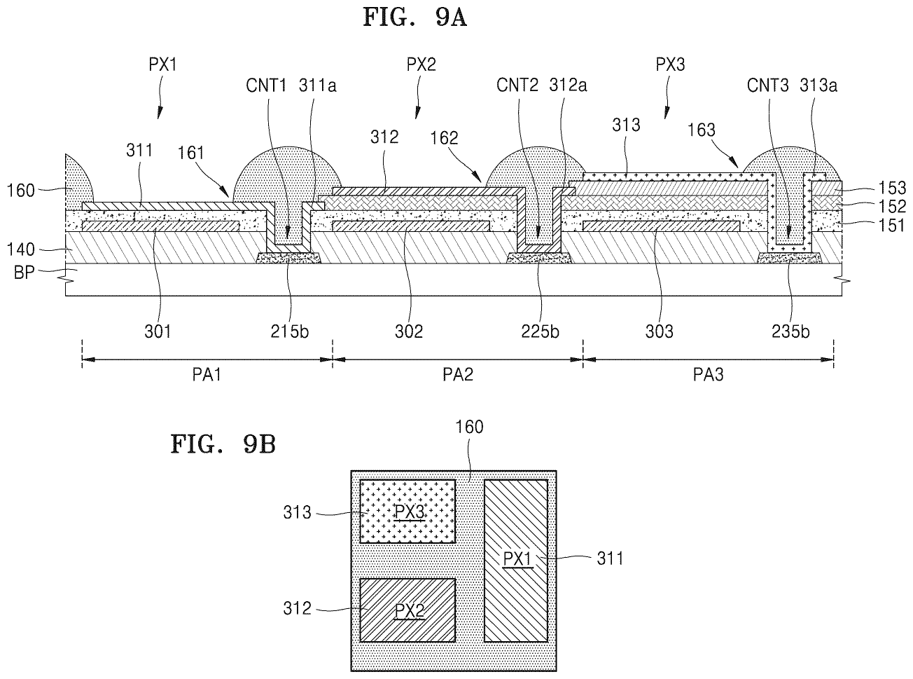

Referring to FIGS. 9A and 9B, a pixel defining layer 160 may be formed or provided on the first inorganic layer 151, the second inorganic layer 152, and the third inorganic layer 153. The pixel defining layer 160 may have a first pixel opening 161 that covers the edges of the first pixel electrode 311, the second pixel electrode 312, and the third pixel electrode 313 and exposes the central portion of the first pixel electrode 311 to define the first emission area EA1, a second pixel opening 162 that exposes the central portion of the second pixel electrode 312 to define the second emission area EA2, and a third pixel opening 163 that exposes the central portion of the third pixel electrode 313 to define the third emission area EA3. The pixel defining layer 160 may be formed or provided to cover the first protrusion 311a, the second protrusion 312a, and the third protrusion 313a and overlap the first contact, the second contact, and the third contact. According to one or more embodiments, because the first contact, the second contact, and the third contact are arranged or provided so as not to overlap the first emission area EA1, the second emission area EA2, and the third emission area EA3, a reduction in aperture ratio may be prevented or reduced. The pixel defining layer 160 may include an organic material and may be formed or provided by inkjet printing.

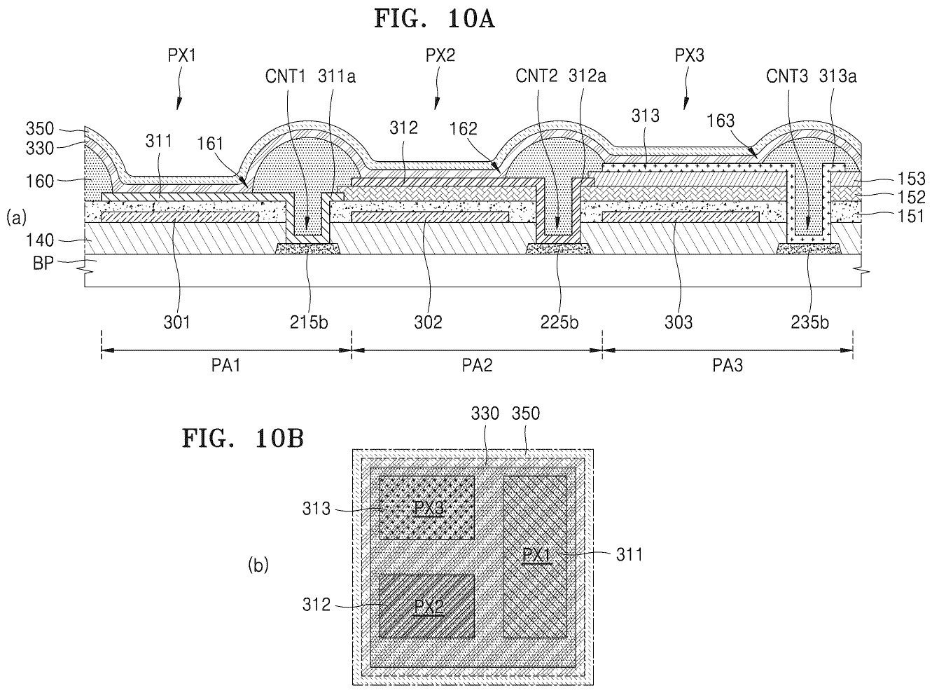

Referring to FIGS. 10A and 10B, an intermediate layer 330 including an emission layer may be formed or provided on the substrate. The intermediate layer 330 may have an integral shape across the first pixel electrode 311, the second pixel electrode 312, and the third pixel electrode 313, but embodiments of the present disclosure are not limited thereto. In addition to the emission layer, the intermediate layer 330 may also include a hole injection layer, a hole transport layer, and/or an electron transport layer as desired or necessary. The layers included in the intermediate layer 330 may also have an integral shape across the first pixel electrode 311, the second pixel electrode 312, and the third pixel electrode 313.

Thereafter, an opposite electrode 350 may be formed or provided to cover the intermediate layer 330 over the entire substrate (or over the substrate entirely). The opposite electrode 350 may also have an integral shape across the first pixel electrode 311, the second pixel electrode 311, and the third pixel electrode 313. The opposite electrode 350 may include a transmissive conductive (e.g., electrically conductive) layer including ITO, In₂O₃, and/or IZO, and may also include a semi-transmissive layer including metal, such as Al, Li, Mg, Yb, and/or Ag.

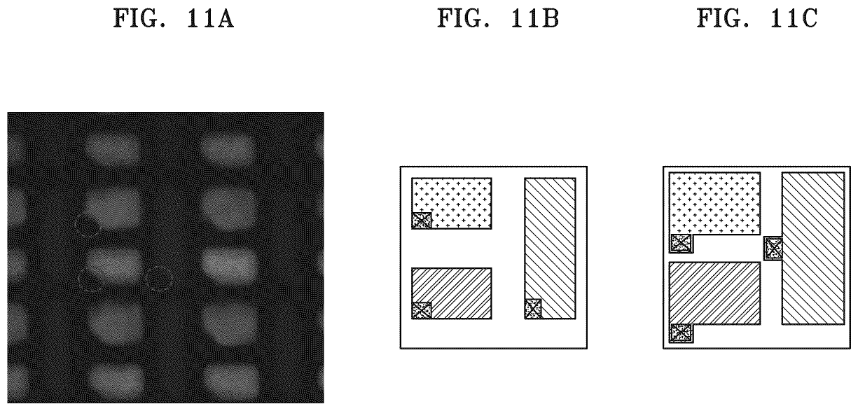

FIGS. 11A to 11C are a photograph and explanatory diagrams illustrating that a display device according to one or more embodiments has a better aperture ratio than a comparative example.

FIG. 11A is a photograph of the display device according to the comparative example, and FIG. 11B is an explanatory diagram of the display device according to the comparative example. FIG. 11C is an explanatory diagram of the display device 10 according to one or more embodiments.

The comparative example in FIG. 11A and FIG. 11B discloses a display device that corresponds to a display panel of a HMD that is generally available or generally used. The pixels included in the display device of the comparative example may not ensure or provide the maximum aperture ratio. In more detail, a pixel electrode of the comparative example is formed or provided so that a contact portion to which a pixel circuit is connected overlaps an emission portion of an OLED (a dashed circular portion in the drawing), which causes a reduction in aperture ratio.

In contrast, the display device according to one or more embodiments may maximize or increase (or enhance) light extraction efficiency by employing the OLED to which the resonance structure is applied. In one or more embodiments, the contacts of each of the pixel electrodes may be arranged or provided outside the emission area to ensure or provide the maximum aperture ratio (FIG. 11C).

In one or more embodiments, each pixel may be arranged or provided to have only the pixel circuit and one contact, and the contact may be arranged or provided outside the emission area. Accordingly, there may be an effect of maximizing or increasing the aperture ratio.

Furthermore, according to one or more embodiments, the reflective electrodes may be arranged or provided in an isolated shape to separate the contacts of the reflective electrodes and one or more other layers. Accordingly, there may be an effect of maximizing or increasing the gap between the reflective electrodes. By maximizing or increasing the gap between the reflective electrodes, light of a particular wavelength may be resonated more effectively or suitably and color gamut and light emission efficiency may be improved or enhanced.

According to one or more embodiments, because the pixel electrodes are arranged or provided in different layers for each pixel, there may be an effect of minimizing or reducing the gap between the pixels. In one or more embodiments, by respectively arranging or providing the first pixel electrode, the second pixel electrode, and the third pixel electrode on the first inorganic layer, the second inorganic layer, and the third inorganic layer, the gap between the pixel electrodes may be minimized or reduced and the aperture ratio may be maximized or increased.

In one or more embodiments, the display device 10 as described in one or more embodiments may be applied to an electronic apparatus.

For example, the electronic apparatus of the present disclosure may include the display device 10 as described in one or more embodiments and may further include at least one selected from among a processor, a memory, an input module, a power module, an internal module, and/or an external module.

The processor may execute software stored in the memory to control at least one other component (e.g., a hardware component and/or a software component) of the electronic apparatus connected to the processor and perform one or more suitable data processing or calculations.

The input module may receive, from the outside of the electronic apparatus (e.g., a user and/or an external electronic apparatus), commands or data to be used by the components of the electronic apparatus (e.g., the processor, a sensor module, and/or an audio output module).

The power module may supply power to the components of the electronic apparatus.

The electronic apparatus may further include the internal module and the external module. The internal module may include a sensor module, an antenna module, and/or an audio output module. The external module may include a camera module, a light module, and/or a communication module.

The electronic apparatus may be one or more suitable kinds or types of apparatuses. The electronic apparatus may include, for example, at least one selected from among a portable communication device (e.g., a smartphone), a computer device, a portable multimedia device, a portable medical device, a camera, a wearable device, a VR device, a VR system, and/or a home appliance. The electronic apparatus according to one or more embodiments is not limited to the devices as described in one or more embodiments.

Each of the embodiments as disclosed herein may be implemented independently, but the structure of each of the embodiments may be applied in combination to other embodiments.

According to one or more embodiments, a high-resolution display device may be provided. The scope of the disclosure is not limited by such an effect.

Although one or more embodiments of the present disclosure have been described with reference to the accompanying drawings, it should be understood that the present disclosure should not be limited to these embodiments but one or more suitable changes and modifications can be made within the spirit and scope of the appended claims and equivalents thereof, the detailed description of the present disclosure, and the accompanying drawings.

Specific executions described in the present disclosure are one embodiment, which does not limit the scope of the embodiments in any way. In one or more embodiments, if (e.g., when) there is no specific mention, such as “essential,” “important,” and/or the like, it may not be a necessary component for the application of the present disclosure.

The use of the definite article “the” and similar demonstratives in the present disclosure (for example, the claims) is to be construed to cover both (e.g., simultaneously) the singular and the plural. In one or more embodiments, if (e.g., when) a range is described, it refers to that individual values within the range are applied (unless otherwise indicated herein). This is substantially the same as stating each individual value that constitutes the range in the detailed description. Finally, operations that constitute methods according to one or more embodiments may be performed in any suitable order unless otherwise indicated herein or otherwise clearly contradicted by context. Embodiments of the present disclosure are not necessarily limited by the order of description of operations. The use of any and all examples or exemplary terms provided in certain embodiments is simply intended to describe the embodiments in more detail, and the scope of the embodiments is not limited by the examples or exemplary terms unless otherwise claimed. In one or more embodiments, it will be understood by those of ordinary skill in the art that one or more suitable modifications, combinations, and changes may be made according to design or arrangement conditions and factors within the spirit and scope of the appended claims or equivalents thereof.

What is claimed is:

1. A display device comprising:
a substrate having pixel areas comprising a first pixel area, a second pixel area, and a third pixel area;
a pixel circuit on the substrate;
reflective electrodes provided on the substrate and respectively provided in the pixel areas;
a first inorganic layer covering the reflective electrodes and provided over the substrate entirely;
a first pixel electrode provided in the first pixel area on the first inorganic layer and contacting the pixel circuit;
a second inorganic layer covering the first inorganic layer and provided in the second pixel area and the third pixel area;
a second pixel electrode provided in the second pixel area on the second inorganic layer and contacting the pixel circuit;
a third inorganic layer covering the second inorganic layer and provided in the third pixel area;
a third pixel electrode provided in the third pixel area on the third inorganic layer and contacting the pixel circuit; and
a pixel defining layer comprising pixel openings respectively corresponding to the first pixel electrode, the second pixel electrode, and the third pixel electrode and covering edges of the first pixel electrode, the second pixel electrode, and the third pixel electrode,
wherein contacts of each of the first pixel electrode, the second pixel electrode, and the third pixel electrode with the pixel circuit are in an area that overlaps the pixel defining layer.

2. The display device as claimed in claim 1, wherein each of the contacts is outside an emission area defined by each of the pixel openings.

3. The display device as claimed in claim 1, wherein each of the reflective electrodes has an isolated shape that corresponds to each of the pixel areas.

4. The display device as claimed in claim 1, wherein each of the reflective electrodes has an area equal to or larger than an area of each of the pixel openings.

5. The display device as claimed in claim 1, wherein each of the reflective electrodes comprises a material having a reflectivity higher than a reflectivity of each of the first pixel electrode, the second pixel electrode, and the third pixel electrode.

6. The display device as claimed in claim 5, wherein each of the reflective electrodes comprises a stack of a transmissive conductive layer and a reflective metal layer.

7. The display device as claimed in claim 1, wherein each of the first inorganic layer, the second inorganic layer, and the third inorganic layer comprises a transmissive inorganic material.

8. The display device as claimed in claim 1, wherein the reflective electrodes comprise:
a first reflective electrode in the first pixel area;
a second reflective electrode in the second pixel area; and
a third reflective electrode in the third pixel area,
wherein each of the first reflective electrode, the second reflective electrode, and the third reflective electrode has an isolated shape, and
wherein a distance between the first reflective electrode and the first pixel electrode, a distance between the second reflective electrode and the second pixel electrode, and a distance between the third reflective electrode and the third pixel electrode are different from each other.

9. The display device as claimed in claim 1, wherein each of the first pixel electrode, the second pixel electrode, and the third pixel electrode comprises a transmissive conductive oxide.

10. The display device as claimed in claim 8, wherein the first pixel electrode has an area larger than an area of the first reflective electrode, the second pixel electrode has an area larger than an area of the second reflective electrode, and the third pixel electrode has an area larger than an area of third reflective electrode.

11. The display device as claimed in claim 1, wherein each of the first pixel electrode, the second pixel electrode, and the third pixel electrode comprises a protrusion that protrudes outside an emission area defined by each of the pixel openings on a plane parallel to the substrate, and
the protrusion overlaps the pixel defining layer.

12. A method of manufacturing a display device, the method comprising:
preparing a substrate having pixel areas comprising a first pixel area, a second pixel area, and a third pixel area;
providing a pixel circuit on the substrate;
providing reflective electrodes in the pixel areas, respectively;
providing a first inorganic layer that covers the reflective electrodes over the substrate entirely;
providing a first pixel electrode provided in the first pixel area on the first inorganic layer and contacting the pixel circuit;
providing a second inorganic layer that covers the first inorganic layer and provided in the second pixel area and the third pixel area;
providing a second pixel electrode provided in the second pixel area on the second inorganic layer and contacting the pixel circuit;
providing a third inorganic layer that covers the second inorganic layer and provided in the third pixel area;
providing a third pixel electrode provided in the third pixel area on the third inorganic layer and contacting the pixel circuit; and
providing a pixel defining layer comprising pixel openings respectively corresponding to the first pixel electrode, the second pixel electrode, and the third pixel electrode and covering edges of the first pixel electrode, the second pixel electrode, and the third pixel electrode,
wherein the contacting of each of the first pixel electrode, the second pixel electrode, and the third pixel electrode with the pixel circuit is in an area that overlaps the pixel defining layer.

13. The method as claimed in claim 12, wherein each of the reflective electrodes has an isolated shape that corresponds to each of the pixel areas.

14. The method as claimed in claim 12, wherein each of the reflective electrodes comprises a material having a reflectivity higher than a reflectivity of each of the first pixel electrode, the second pixel electrode, and the third pixel electrode.

15. The method as claimed in claim 14, wherein each of the reflective electrodes comprises a stack of a transmissive conductive layer and a reflective metal layer.

16. The method as claimed in claim 12, wherein each of the first inorganic layer, the second inorganic layer, and the third inorganic layer comprises a transmissive inorganic material.

17. The method as claimed in claim 12, wherein the pixel defining layer is provided to directly cover contacts of each of the first pixel electrode, the second pixel electrode, and the third pixel electrode with the pixel circuit.

18. An electronic apparatus comprising a display device,
wherein the display device comprises:
a substrate having pixel areas comprising a first pixel area, a second pixel area, and a third pixel area;
a pixel circuit on the substrate;
reflective electrodes provided on the substrate and respectively provided in the pixel areas;
a first inorganic layer covering the reflective electrodes and provided over the substrate entirely;
a first pixel electrode provided in the first pixel area on the first inorganic layer and contacting the pixel circuit;
a second inorganic layer covering the first inorganic layer and provided in the second pixel area and the third pixel area;
a second pixel electrode provided in the second pixel area on the second inorganic layer and contacting the pixel circuit;
a third inorganic layer covering the second inorganic layer and provided in the third pixel area;
a third pixel electrode provided in the third pixel area on the third inorganic layer and contacting the pixel circuit; and
a pixel defining layer comprising pixel openings respectively corresponding to the first pixel electrode, the second pixel electrode, and the third pixel electrode and covering edges of the first pixel electrode, the second pixel electrode, and the third pixel electrode,
wherein contacts of each of the first pixel electrode, the second pixel electrode, and the third pixel electrode with the pixel circuit are in an area that overlaps the pixel defining layer.

19. The electronic apparatus as claimed in claim 18, wherein each of the contacts is outside an emission area defined by each of the pixel openings.

20. The electronic apparatus as claimed in claim 18, wherein each of the first pixel electrode, the second pixel electrode, and the third pixel electrode comprises a protrusion that protrudes outside an emission area defined by each of the pixel openings on a plane parallel to the substrate, and
the protrusion overlaps the pixel defining layer.
